(19) United States
(12) Patent Application Publication
(10) Pub. No.: US 2026/0353553 A1
(43) Pub. Date: Nov. 5, 2026

(54) Circuit Apparatus And Vibration Device

(71) Applicant: SEIKO EPSON CORPORATION, Tokyo (JP)

(72) Inventor: Koichi MIZUGAKI, Suwa (JP)

(21) Appl. No.: 19/662,277

(22) Filed: Apr. 29, 2026

(30) Foreign Application Priority Data
Apr. 30, 2025 (JP) 2025-075085

(51) Int. Cl. H05K 1/02

(52) U.S. Cl. CPC H05K 1/0284; H05K 2201/10015

(57) ABSTRACT

A circuit apparatus includes a substrate of a first conductivity type, a well of the first conductivity type provided in the substrate, a well of a second conductivity type provided in the substrate, a pad, and a MIM capacitor having an electrode, another electrode, and a dielectric layer provided between the electrodes. The well of the second conductivity type and the pad are electrically connected by a first conductive path. One electrode out of the electrodes is electrically connected to the pad by a second conductive path, and the other electrode out of the electrodes is electrically connected to the well of the first conductivity type by a third conductive path. A resistance value of the second conductive path is greater than a resistance value of the first conductive path.

The present application is based on, and claims priority from JP Application Serial Number 2025-075085, filed Apr. 30, 2025, the disclosure of which is hereby incorporated by reference herein in its entirety.

### BACKGROUND

### 1. TECHNICAL FIELD

The present disclosure relates to a circuit apparatus, a vibration device, and the like.

### 2. RELATED ART

JP-A-2011-109074 discloses a circuit apparatus including a pad to which a signal is input, an analog circuit that performs analog processing on the signal input via the pad, and a MIM capacitor provided between a signal input node of the analog circuit and the pad. In this circuit apparatus, the pad and one end of the MIM capacitor are connected to each other by pad wiring formed by an uppermost metal layer.

However, it has been found that there is a possibility that the MIM capacitor is affected by static electricity in such wiring connection as in JP-A-2011-109074.

### SUMMARY

An aspect of the present disclosure relates to a circuit apparatus including a substrate of a first conductivity type, a first well of the first conductivity type provided in the substrate, a second well of a second conductivity type provided in the substrate, a pad, and a MIM capacitor including a first electrode, a second electrode, and a dielectric layer provided between the first electrode and the second electrode. The second well and the pad are electrically connected by a first conductive path, one electrode out of the first electrode and the second electrode and the pad are electrically connected by a second conductive path, another electrode out of the first electrode and the second electrode and the first well are electrically connected by a third conductive path, and a resistance value of the second conductive path is greater than a resistance value of the first conductive path.

Another aspect of the present disclosure relates to a circuit apparatus including a substrate of a first conductivity type, a first well of the first conductivity type provided in the substrate, a second well of a second conductivity type provided in the substrate, a pad, and a MIM capacitor including a first electrode, a second electrode, and a dielectric layer provided between the first electrode and the second electrode. The second well and the pad are electrically connected by a first conductive path, one electrode out of the first electrode and the second electrode and the pad are electrically connected by a second conductive path, another electrode out of the first electrode and the second electrode and the first well are electrically connected by a third conductive path, and the second conductive path includes first wiring of a metal layer that is a same layer as or a layer above a metal layer of the first electrode, and second wiring of a metal layer below the metal layer of the first electrode.

Another aspect of the present disclosure relates to a vibration device including the circuit apparatus described above, a through electrode provided in the substrate of the circuit apparatus, a vibration element electrically connected to the through electrode, and a lid that accommodates the vibration element together with the substrate.

### BRIEF DESCRIPTION OF THE DRAWINGS

FIG. 1 is a cross-sectional view of a circuit apparatus of the present embodiment.

FIG. 2 is a cross-sectional view of a comparative example.

FIG. 3 is an explanatory diagram for describing an issue of the comparative example.

FIG. 4 is an explanatory diagram for describing a discharge path of static electricity in the circuit apparatus of the present embodiment.

FIG. 5 is a cross-sectional view illustrating another arrangement example of a MIM capacitor of the circuit apparatus.

FIG. 6 is a plan view illustrating ALE wiring of the circuit apparatus.

FIG. 7 is a plan view illustrating a MIM arrangement of the circuit apparatus.

FIG. 8 is a plan view illustrating ALD wiring of the circuit apparatus.

FIG. 9 is a plan view illustrating the MIM arrangement of the circuit apparatus.

FIG. 10 is a plan view illustrating ALC wiring of the circuit apparatus.

FIG. 11 is a plan view illustrating ALB wiring of the circuit apparatus.

FIG. 12 is a plan view illustrating ALA wiring of the circuit apparatus.

FIG. 13 is a diagram illustrating a detailed configuration example of the circuit apparatus of the present embodiment.

FIG. 14 is a cross-sectional view illustrating a configuration example of a vibration device according to the present embodiment.

FIG. 15 is a diagram illustrating an example of a manufacturing process of the vibration device.

FIG. 16 is a diagram illustrating an example of the manufacturing process of the vibration device.

FIG. 17 is a diagram illustrating an example flow of the manufacturing process of the vibration device.

FIG. 18 is a diagram illustrating an example flow of the manufacturing process of the vibration device.

FIG. 19 is a diagram illustrating an example flow of the manufacturing process of the vibration device.

FIG. 20 is a diagram illustrating an example flow of the manufacturing process of the vibration device.

FIG. 21 is a diagram illustrating an example flow of the manufacturing process of the vibration device.

### DESCRIPTION OF EMBODIMENTS

Hereinafter, the present embodiment will be described. The present embodiment described below does not unduly limit the contents described in the claims. In addition, not all configurations described in the present embodiment are essential components. In each of the following drawings, some components may be omitted for convenience of description. In each of the drawings, a dimensional ratio of each component is different from an actual ratio to facilitate understanding.

### 1. Circuit apparatus

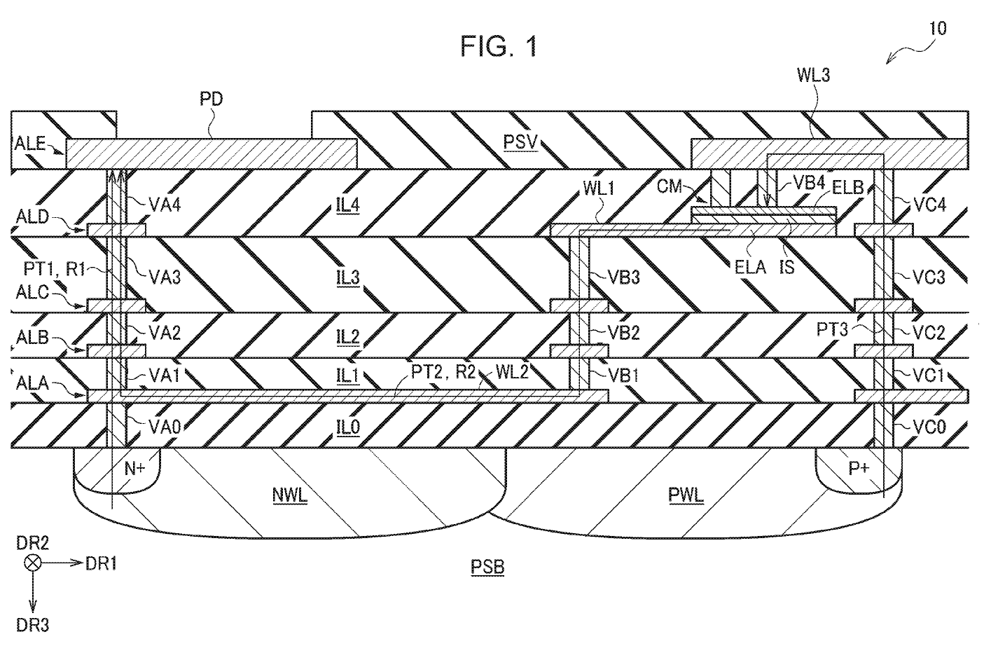

FIG. 1 is a cross-sectional view illustrating a configuration example of a circuit apparatus 10 of the present embodiment. As illustrated in FIG. 1, the circuit apparatus 10 includes a substrate PSB, wells PWL and NWL, a pad PD, and a MIM capacitor CM. In FIG. 1, directions DR1 and DR2 are directions along a surface of the substrate PSB, and the direction DR1 and the direction DR2 are directions orthogonal to each other. A direction DR3 is a direction orthogonal to the substrate PSB, and the direction DR3 is a direction orthogonal to the direction DR1 and the direction DR2. FIG. 1 is a cross-sectional view of the circuit apparatus 10 in a side view along the direction DR2. The directions DR1, DR2, and DR3 are a first direction, a second direction, and a third direction, respectively. In the present embodiment, the term "orthogonal" includes "substantially orthogonal".

The substrate PSB is a substrate of a first conductivity type, specifically, for example, a P-type substrate. The well PWL is a first well of the first conductivity type provided in the substrate PSB, and is specifically, for example, a P-type well. The well NWL is a second well of a second conductivity type provided in the substrate PSB, and is specifically, for example, an N-type well. In the present embodiment, a case where the first conductivity type is a P-type and the second conductivity type is an N-type will be mainly described as an example. However, a modification in which the first conductivity type is set as an N-type and the second conductivity type is set as a P-type is also possible.

The P-type substrate PSB is a semiconductor substrate, and is set to a potential of GND that is a ground by, for example, a P-type diffusion region (not illustrated). Here, GND is a power supply potential on a low potential side and is also referred to as VSS. The P-type well PWL is formed in the substrate PSB and is set to the potential of GND by, for example, a P-type diffusion region P+. The N-type well NWL is formed in the substrate PSB and is set to a potential of VDD by, for example, an N-type diffusion region N+. Here, VDD is a power supply potential on a high potential side.

The circuit apparatus 10 includes a plurality of metal layers ALA, ALB, ALC, ALD, and ALE. These metal layers are, for example, aluminum metal layers, in which the metal layer ALA is a lowermost metal layer, and the metal layer ALE is an uppermost metal layer. The uppermost metal layer ALE is a metal layer that is thicker than the other metal layers ALA, ALB, ALC, and ALD. Furthermore, insulating layers IL1, IL2, IL3, and IL4 are provided between the respective metal layers ALA, ALB, ALC, ALD, and ALE. An insulating layer IL0 is provided between the metal layer ALA and the substrate PSB and between the metal layer ALA and the wells PWL and NWL. In the present embodiment, a case where the plurality of metal layers are five metal layers will be mainly described as an example, but the present disclosure is not limited thereto, and the plurality of metal layers may be four or fewer metal layers or six or more metal layers.

The MIM capacitor CM is a capacitor having a metal-insulator-metal structure and includes electrodes ELA and ELB and a dielectric layer IS provided between the electrodes ELA and ELB. The electrode ELA is a first electrode and is, for example, a lower electrode of the MIM capacitor CM. In FIG. 1, the electrode ELA is formed by the metal layer ALD. The electrode ELB is a second electrode and is, for example, an upper electrode of the MIM capacitor CM. The electrode ELB is formed by a metal layer for MIM provided between the metal layer ALE and the metal layer ALD. That is, the electrode ELB is formed by a metal layer for MIM provided in the insulating layer IL4 between the metal layer ALE and the metal layer ALD. Since a thickness of the dielectric layer IS which is an insulating layer can be reduced in the MIM capacitor CM, there is an advantage that a large capacitance value can be obtained with a small layout area. In addition, since the MIM capacitor CM can be formed by effectively utilizing a space above a circuit element and circuit wiring, there is an advantage that a large capacitance value can be obtained while suppressing an increase in a layout area of the circuit apparatus 10. In addition, since the MIM capacitor CM has low voltage dependency, there is an advantage that analog characteristics such as noise characteristics are also satisfactory.

In the present embodiment, the MIM capacitor CM is used as, for example, a power supply condenser between VDD and GND. That is, the MIM capacitor CM is used as, for example, a bypass capacitor provided between VDD and GND.

The pad PD is a terminal of the circuit apparatus 10 which is, for example, a semiconductor chip, and is a terminal for external connection. For example, in a region of the pad PD, the metal layer ALE is exposed from a passivation film PSV which is an insulating layer, and the pad PD which is a terminal of the circuit apparatus 10 is formed by the exposed metal layer ALE or the like. The pad PD is a pad to which the power supply voltage of VDD is supplied when the circuit apparatus 10 operates.

In FIG. 1, the well NWL and the pad PD are electrically connected by a first conductive path PT1. The conductive path is, for example, a path formed by a conductive member such as a metal layer or a via. For example, the first conductive path PT1 includes vias VA0, VA1, VA2, VA3, and VA4, and the pad PD is electrically connected to the well NWL through these vias. The vias VA1, VA2, VA3, and VA4 are vias that connect the metal layers ALA and ALB, ALB and ALC, ALC and ALD, and ALD and ALE, respectively, and are realized by, for example, tungsten plugs or the like. The via VA0 connects the metal layer ALA and the diffusion layer N+, and is also called a contact. The pad PD is electrically connected to the well NWL through the vias VA4, VA3, VA2, VA1, and VA0 and the diffusion layer N+. It should be noted that a connection in the present embodiment is an electrical connection even when there is no explicit description thereof. An electrical connection is a connection through which an electrical signal can be transmitted, and is a connection through which information based on an electrical signal can be transmitted. An electrical connection may be a connection via a passive element or the like.

In the present embodiment, one electrode out of the electrode ELA and the electrode ELB of the MIM capacitor CM is electrically connected to the pad PD by a second conductive path PT2. In FIG. 1, one of the electrodes is the electrode ELA, and the electrode ELA of the capacitor CM and the pad PD are electrically connected by a second conductive path PT2. In FIG. 1, the second conductive path PT2 includes the wiring WL1, vias VB3, VB2, and VB1, the wiring WL2, and the vias VA1, VA2, VA3, and VA4. The wiring WL1 is first wiring and is, for example, wiring of the metal layer ALD. That is, the wiring WL1 is the wiring of the metal layer ALD that is the same layer as the metal layer of the electrode ELA. The wiring WL2 is second wiring and is, for example, wiring of the metal layer ALA. That is, the wiring WL2 is the wiring of the metal layer ALA below the metal layer ALD of the electrode ELA. The metal layer ALA is, for example, the lowermost metal layer. The vias VB3, VB2, and VB1 are vias that connect the metal layers ALD and ALC, ALC and ALB, and ALB and ALA, respectively. The vias VA1, VA2, VA3, and VA4 are vias connecting the metal layers ALA and ALB, ALB and ALC, ALC and ALD, and ALD and ALE, respectively.

In addition, in the present embodiment, the other electrode out of the electrode ELA and the electrode ELB of the MIM capacitor CM and the well PWL are electrically connected by a third conductive path PT3. In FIG. 1, the other electrode is the electrode ELB, and the electrode ELB of the capacitor CM and the well PWL are electrically connected to each other by the third conductive path PT3. The third conductive path PT3 includes a via VB4, wiring WL3, and vias VC4, VC3, VC2, VC1, and VC0 in FIG. 1. The via VB4 is a via that connects the electrode ELB and the wiring WL3. The wiring WL3 is wiring of the metal layer ALE. That is, the wiring WL3 is the wiring of the metal layer ALE above the metal layer ALD of the electrode ELA. The metal layer ALE is the uppermost metal layer. The vias VC4, VC3, VC2, and VC1 are vias connecting the metal layers ALE and ALD, ALD and ALC, ALC and ALB, and ALB and ALA, respectively. The via VC0 connects the metal layer ALA and a diffusion layer P+, and is also called a contact. The electrode ELB of the capacitor CM is electrically connected to the well PWL through the via VB4, the wiring WL3, the vias VC4, VC3, VC2, VC1, and VC0, and the diffusion layer P+.

In the present embodiment, a resistance value R2 of the second conductive path PT2 is greater than a resistance value R1 of the first conductive path PT1, and a relationship R2 > R1 is established. The resistance value R1 is a resistance value due to, for example, parasitic resistances of the vias VA0, VA1, VA2, VA3, and VA4 and the like. The resistance value R2 is a resistance value due to, for example, parasitic resistances of the wiring WL1 and wiring WL2, the vias VB3, VB2, VB1, VA1, VA2, VA3, and VA4, and the like. When a resistance value of the third conductive path PT3 is set as R3, a relationship R2 + R3 > R1 may be satisfied.

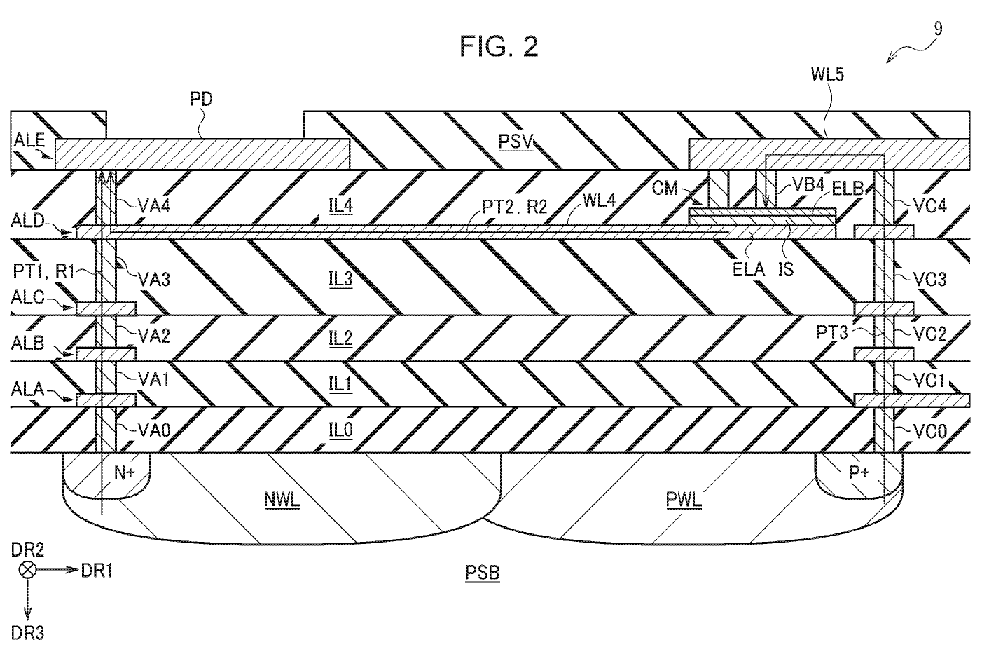

For example, FIG. 2 is a cross-sectional view illustrating a configuration example of a circuit apparatus 9 of a comparative example of the present embodiment. In the comparative example of FIG. 2, the electrode ELA of the MIM capacitor CM is electrically connected to the pad PD through wiring WL4 of the metal layer ALD and the via VA4. In addition, the electrode ELB of the capacitor CM is electrically connected to the well PWL through wiring WL5 and the vias VC4, VC3, VC2, VC1, and VC0 of the metal layer ALE.

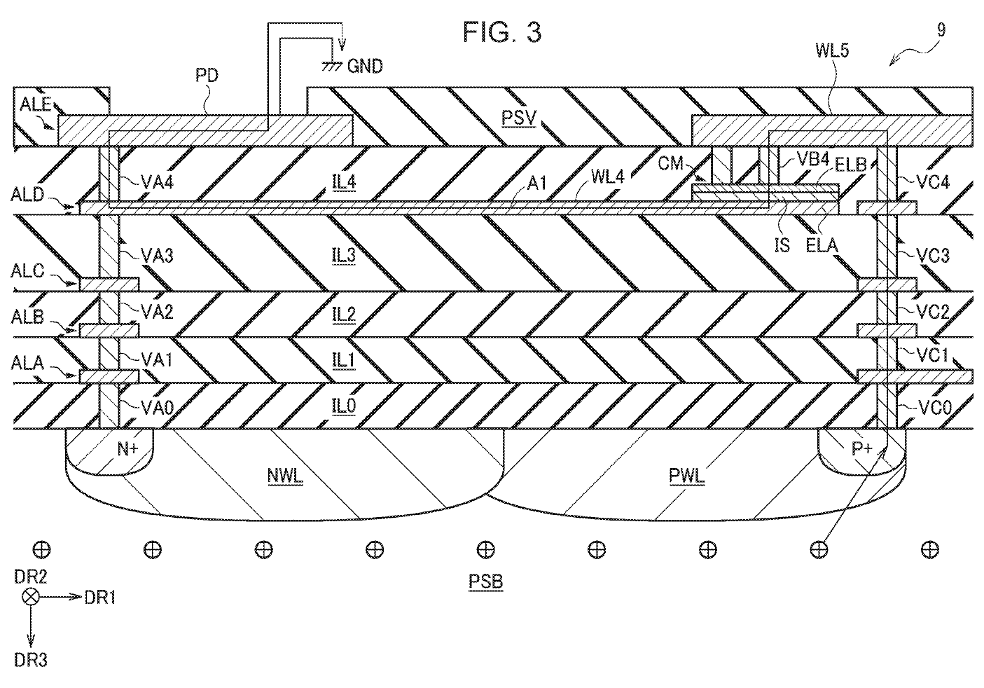

That is, in the present embodiment illustrated in FIG. 1, the second conductive path PT2 connecting the electrode ELA of the capacitor CM and the pad PD is a path including the wiring WL1, the vias VB3, VB2, and VB1, the wiring WL2, and the vias VA1, VA2, VA3, and VA4. On the other hand, the second conductive path PT2 in the comparative example of FIG. 2 is a path including only the wiring WL4 and the via VA4. Therefore, the resistance value R2 of the second conductive path PT2 in the comparative example is less than the resistance value R2 of the second conductive path PT2 in the present embodiment. Thus, the relationship R2 > R1 is established in the present embodiment of FIG. 1, but the relationship R2 > R1 is not established in the comparative example of FIG. 2. As a result, it has been found that an issue described with reference to FIG. 3 occurs.

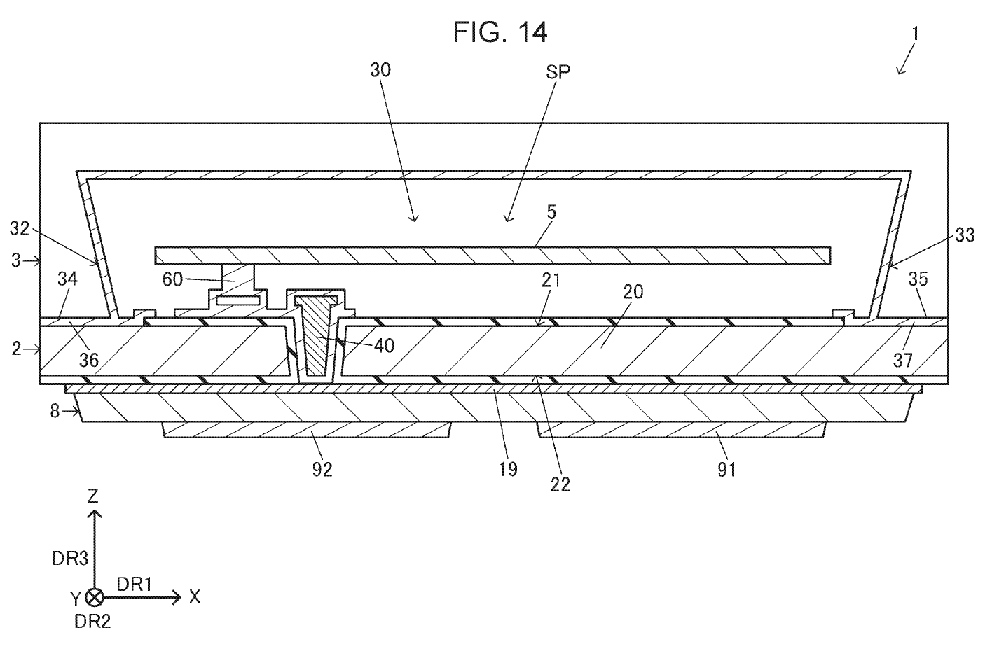

In FIG. 3, charges are accumulated in the substrate PSB since the substrate PSB is charged. For example, in a vibration device 1 of WLP as illustrated in FIG. 14 to be described later, charges are accumulated in the substrate PSB of the circuit apparatus 10 via a lid 3 or the like in the manufacturing process or the like. Although FIG. 3 illustrates a case where positive charges are accumulated in the substrate PSB, the accumulated charges may be negative charges.

In FIG. 3, since the pad PD is set to the potential of GND, the charges accumulated in the substrate PSB are discharged through a path denoted by A1. For example, since one of external connection terminals 91 and 92 illustrated in FIG. 14 is electrically connected to the pad PD, when the one of the external connection terminals 91 and 92 is brought into contact with an object having the potential of GND, such a situation occurs that static charges are discharged through the path denoted by A1 in FIG. 3. For example, when the pad PD is set to the potential of GND, the potential of the electrode ELA of the MIM capacitor CM decreases via the second conductive path PT2, and a potential difference between the potential of the electrode ELA and the potential of the electrode ELB increases. When the potential difference between the electrode ELA and the electrode ELB exceeds a withstand voltage of the insulating layer which is the dielectric layer IS of the capacitor CM, dielectric breakdown occurs. As a result, as denoted by A1 in FIG. 3, the charges of the substrate PSB are discharged to GND through the well PWL, the vias VC0, VC1, VC2, VC3, and VC4, the wiring WL5, the MIM capacitor CM, the wiring WL4, the via VA4, and the pad PD.

For example, it is useful to provide the capacitor CM having the MIM structure in the circuit apparatus 10 because there are effects of noise resistance and reduction in chip area. However, in the related art, one electrode of the MIM capacitor CM is connected to the pad PD of the power supply of VDD that is a potential different from a potential of the substrate PSB through a path having a low resistance value. For this reason, when the pad PD is grounded to cause discharge, the static charges accumulated in the substrate PSB are discharged through the MIM capacitor CM having a low withstand voltage, and electrostatic breakdown of the MIM capacitor occurs. In particular, in a device having a structure in which the lid 3 is bonded to a rear surface side of the circuit apparatus 10 as in the vibration device 1 of the WLP in FIG. 14, charges are likely to be accumulated in the substrate PSB, and such an issue remarkably occurs.

In this regard, in the present embodiment, the resistance value R2 of the second conductive path PT2 which connects the one electrode ELA of the MIM capacitor CM and the pad PD as described with reference to FIG. 1 is greater than that in, for example, the comparative example of FIG. 2. For example, in FIG. 1, the resistance value R2 is increased by making the second conductive path PT2 a conductive path with a further detour compared to the comparative example of FIG. 2. As a result, the resistance value R2 of the second conductive path PT2 is greater than the resistance value R1 of the first conductive path PT1 connecting the well NWL and the pad PD.

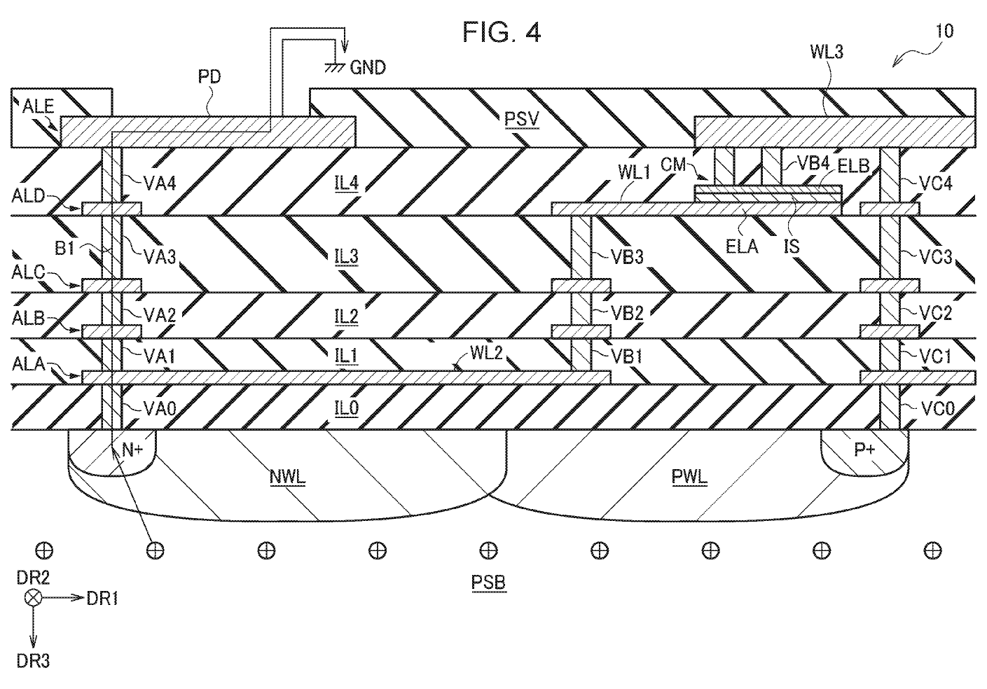

In this way, the charges of the substrate PSB are discharged not through the second conductive path PT2 passing through the MIM capacitor CM but through the first conductive path PT1 as denoted by B1 in FIG. 4. That is, since the resistance value R2 of the second conductive path PT2 is greater than the resistance value R1 of the first conductive path PT1, the charges of the substrate PSB are discharged from the pad PD to GND via the first conductive path PT1 having a small resistance value R1, not via the second conductive path PT2 having a large resistance value R2. Therefore, since the discharge of charges via the MIM capacitor CM as denoted by A1 in FIG. 3 is suppressed, it is possible to prevent the occurrence of electrostatic breakdown of the MIM capacitor CM.

For example, in the above-described comparative example of FIG. 2, when the pad PD is set to the potential of GND, the potential of the electrode ELA of the capacitor CM decreases, and when the potential difference between the electrode ELA and the electrode ELB exceeds the withstand voltage of the insulating layer of the capacitor CM, dielectric breakdown occurs. In contrast, in the present embodiment, since the resistance value R2 of the second conductive path PT2 is large, when the pad PD is set to the potential of GND, the potential of the electrode ELA is less likely to decrease compared to the comparative example, and before the potential of the electrode ELA decreases, as denoted by B1 in FIG. 4, the charges of the substrate PSB are discharged to the GND side through the first conductive path PT1 having a low resistance value R1. Therefore, the potential difference between the electrode ELA and the electrode ELB of the capacitor CM does not exceed the withstand voltage of the insulating film, and the dielectric breakdown can be prevented.

When positive charges are accumulated in the substrate PSB, a discharge path of a PN junction between the substrate PSB and the well NWL in the first conductive path PT1 is a path in a forward direction of the PN junction. On the other hand, when negative charges are accumulated in the substrate PSB, the discharge path of the charges is a path in the reverse direction of the PN junction. However, since a high voltage is applied in electrostatic breakdown, the charges are discharged by avalanche breakdown or the like in the reverse direction.

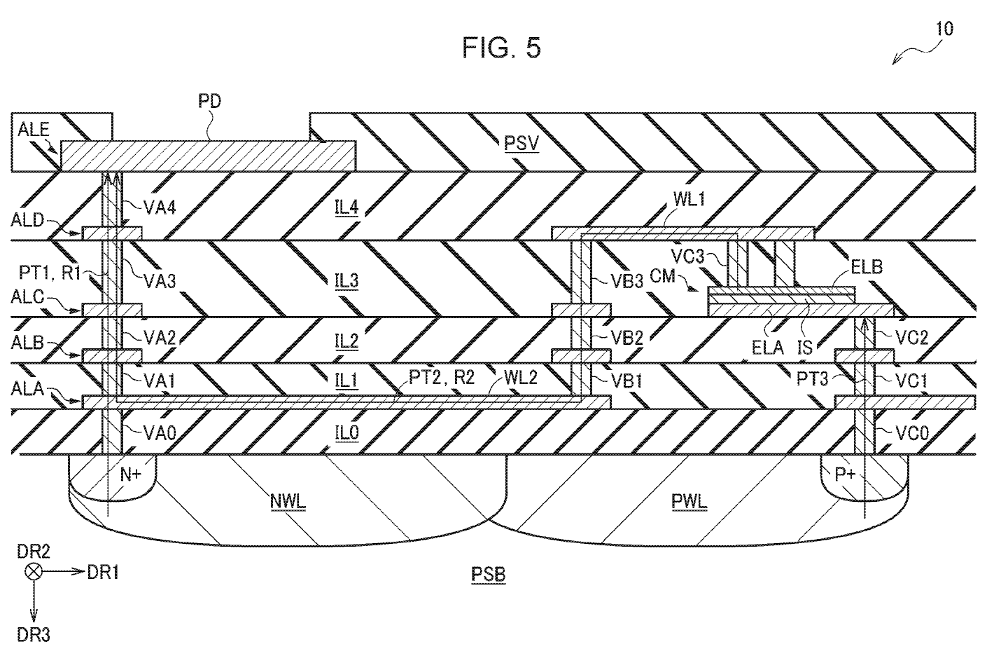

FIG. 5 is a cross-sectional view illustrating another arrangement example of the MIM capacitor CM in the circuit apparatus 10 of the present embodiment. Although the MIM capacitor CM is provided between the metal layer ALE and the metal layer ALD in FIG. 1, the MIM capacitor CM is provided between the metal layer ALD and the metal layer ALC in FIG. 5. That is, the electrode ELA of the capacitor CM is formed by the metal layer ALC, and the electrode ELB is formed by a metal layer for MIM between the metal layers ALD and ALC.

To be more specific, in FIG. 5, the well NWL and the pad PD are electrically connected by the first conductive path PT1 as in FIG. 1. The first conductive path PT1 includes the vias VA0, VA1, VA2, VA3, and VA4, and the pad PD and the well NWL are electrically connected to each other via these vias and the diffusion layer N+.

In addition, in the present embodiment, one electrode out of the electrode ELA and the electrode ELB of the MIM capacitor CM and the pad PD are electrically connected by the second conductive path PT2. In FIG. 5, the one electrode is the electrode ELB, and the electrode ELB of the capacitor CM and the pad PD are electrically connected by the second conductive path PT2. In FIG. 5, the second conductive path PT2 includes the via VC3, the wiring WL1, the vias VB3, VB2, and VB1, the wiring WL2, the vias VA1, VA2, VA3, and VA4. The wiring WL1 is first wiring and is wiring of the metal layer ALD above the metal layer ALC of the electrode ELA. The wiring WL2 is second wiring and is wiring of the metal layer ALA below the metal layer ALC of the electrode ELA. The vias VB3, VB2, and VB1 are vias that connect the metal layers ALD and ALC, ALC and ALB, and ALB and ALA, respectively. The via VC3 is a via that connects the electrode ELB to the wiring WL1 of the metal layer ALD.

In addition, in the present embodiment, the other electrode out of the electrode ELA and the electrode ELB of the MIM capacitor CM and the well PWL are electrically connected by the third conductive path PT3. In FIG. 5, the other electrode is the electrode ELA, and the electrode ELA of the capacitor CM and the well PWL are electrically connected by the third conductive path PT3. In FIG. 5, the third conductive path PT3 includes the vias VC2, VC1, and VC0. The vias VC2 and VC1 are vias that connect ALC and ALB, and ALB and ALA, respectively, and the via VC0 is a contact that connects the metal layer ALA and the diffusion layer P+. The electrode ELA of the capacitor CM is electrically connected to the well PWL through the vias VC2, VC1, and VC0 and the diffusion layer P+.

In FIG. 5 too, the resistance value R2 of the second conductive path PT2 is greater than the resistance value R1 of the first conductive path PT1, and the relationship R2 > R1 is established. The resistance value R1 is a resistance value due to, for example, parasitic resistances of the vias VA4, VA3, VA2, VA1, and VA0, and the like. The resistance value R2 is a resistance value due to, for example, parasitic resistances of the wiring WL1 and wiring WL2, the vias VC3, VB3, VB2, VB1, VA1, VA2, VA3, and VA4, and the like.

Various modifications can be made to the present embodiment. For example, in FIGS. 1 and 5, the wiring WL1 is wiring of the metal layer ALD, but the wiring WL1 may be wiring of a metal layer above or below the metal layer ALD. In addition, in FIGS. 1 and 5, the wiring WL2 is wiring of the lowermost metal layer ALA, but the wiring WL2 may be wiring of a metal layer above the metal layer ALA. Furthermore, in the present embodiment, the relationship R2 > R1 is established by making the second conductive path PT2 a path with a further detour compared to the comparative example, but the detour path of the second conductive path PT2 is not limited to the detour path as illustrated in FIGS. 1 and 5. For example, various modifications can be made such as making the second conductive path PT2 detour from the upper layer to the lower layer like the path through the vias VB3, VB2, and VB1 of FIGS. 1 and 5, then making the second conductive path PT2 detour from the lower layer to the upper layer, further making the second conductive path PT2 detour from the upper layer to the lower layer, and connecting the second conductive path PT2 to the first conductive path PT1. In FIGS. 1 and 5, the resistance value R2 of the second conductive path PT2 is increased by the detour of the path, but the resistance value R2 may be increased by, for example, inserting a resistance element or the like into the second conductive path PT2. For example, the relationship R2 > R1 may be established by providing a resistance element made of polysilicon or the like in the second conductive path PT2.

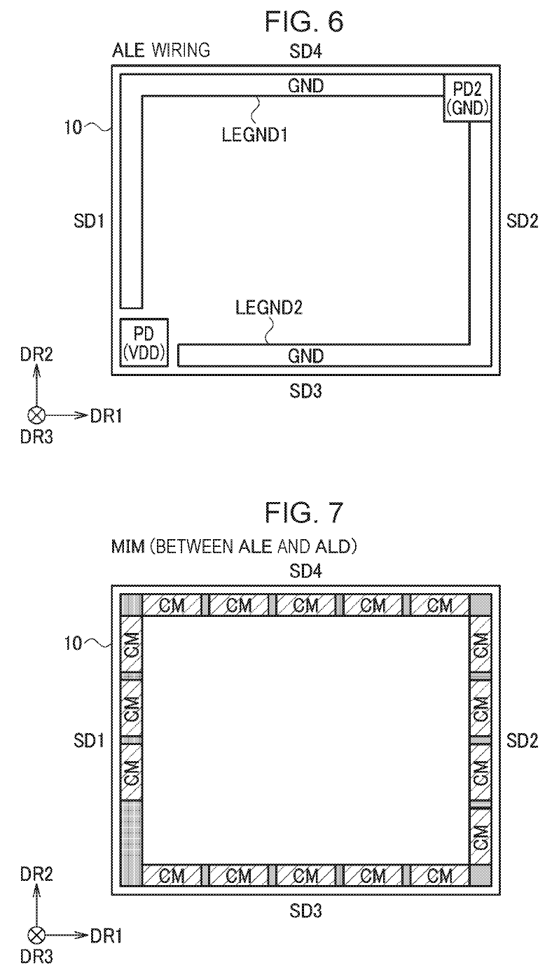

FIGS. 6 to 12 are plan views illustrating metal wiring and a MIM arrangement in the circuit apparatus 10 of the present embodiment. The circuit apparatus 10 has sides SD1, SD2, SD3, and SD4. The side SD2 is an opposite side of the side SD1, and the side SD4 is an opposite side of the side SD3. Furthermore, the direction DR1 is a direction from the side SD1 to the side SD2, and the direction DR2 is a direction from the side SD3 to the side SD4. FIGS. 6 to 12 are plan views each of which is in plan view in the direction DR3 orthogonal to the directions DR1 and DR2.

FIG. 6 is a plan view illustrating layout wiring of the metal layer ALE. In FIG. 6, the metal layer ALE of the pad PD of VDD is arranged in a first corner portion where the side SD1 and the side SD3 intersect, and the metal layer ALE of the pad PD2 of GND is arranged in a second corner portion where the side SD2 and the side SD4 intersect. GND wiring LEGND1 from the pad PD2 is wired along the side SD4 and the side SD1, and GND wiring LEGND2 from the pad PD2 is wired along the side SD2 and the side SD3. That is, the GND wiring LEGND1 and GND wiring LEGND2 formed by the metal layer ALE are wired in a substantially ring shape along an inner periphery of the circuit apparatus 10.

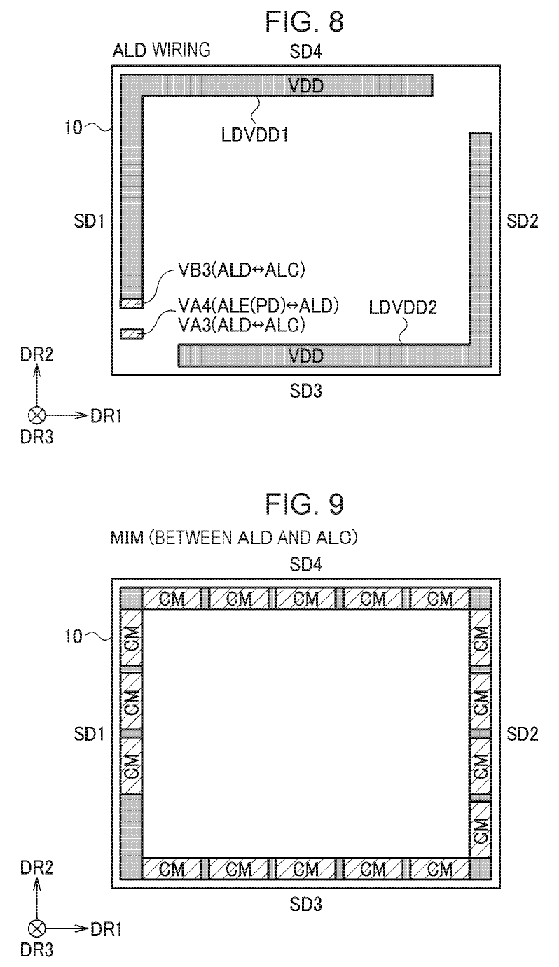

FIG. 7 is a plan view illustrating an arrangement example of the MIM capacitor CM provided between the metal layer ALE and the metal layer ALD described in FIG. 1. In FIG. 7, the MIM capacitor CM is arranged along the GND wiring LEGND1 and GND wiring LEGND2 in FIG. 6 and VDD wiring LDVDD1 and VDD wiring LDVDD2 in FIG. 8, and to be specific, is arranged so as to overlap these wiring lines in plan view. Note that the MIM capacitor CM may be arranged in an inner region of these wiring lines.

FIG. 8 is a plan view illustrating layout wiring of the metal layer ALD. In FIG. 8, the VDD wiring LDVDD1 is wired along the side SD4 and the side SD1, and the VDD wiring LDVDD2 is wired along the side SD2 and the side SD3. That is, the VDD wiring LDVDD1 and VDD wiring LDVDD2 formed by the metal layer ALD are wired in a substantially ring shape along the inner periphery of the circuit apparatus 10.

FIG. 8 also illustrates an arrangement example of the via VB3, the via VA4, and the via VA3 in FIGS. 1 and 5. For example, in an arrangement region of the MIM, the wiring WL1 which is VDD wiring of the metal layer ALD is connected to the lower metal layer ALC through the via VB3. Furthermore, in an arrangement region of the pad PD, the metal layer ALE of the pad PD is connected to the lower metal layer ALD through the via VA4, and the metal layer ALD is connected to the lower metal layer ALC through the via VA3. In practice, a large number of vias VA4 and VA3 are arranged, for example, in a matrix in the arrangement region of the pad PD of the metal layer ALE which has, for example, a rectangular shape.

FIG. 9 is a plan view illustrating an arrangement example of the MIM capacitor CM provided between the metal layer ALD and the metal layer ALC described in FIG. 5. In FIG. 9, the MIM capacitor CM is arranged along the GND wiring LEGND1 and GND wiring LEGND2 of FIG. 6 and the VDD wiring LDVDD1 and VDD wiring LDVDD2 of FIG. 8, and to be specific, is arranged so as to overlap these wiring lines in plan view. Note that the MIM capacitor CM may be arranged in an inner region of these wiring lines.

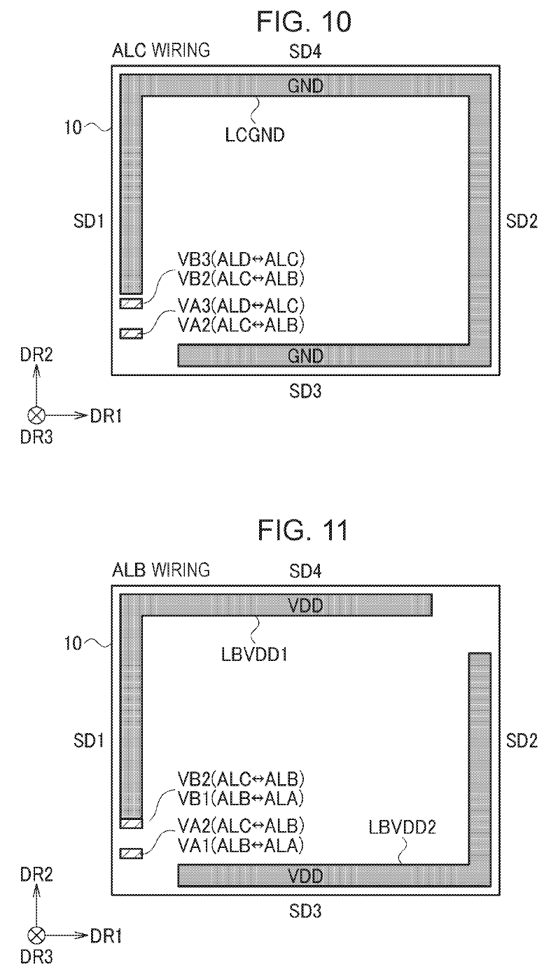

FIG. 10 is a plan view illustrating layout wiring of the metal layer ALC. In FIG. 10, GND wiring LCGND is wired along the sides SD1, SD4, SD2, and SD3. That is, the GND wiring LCGND formed by the metal layer ALC is wired in a substantially ring shape along the inner periphery of the circuit apparatus 10.

FIG. 10 also illustrates an arrangement example of the vias VB3 and VB2 and the vias VA3 and VA2 illustrated in FIGS. 1 and 5. For example, in the arrangement region of the MIM, the metal layer ALD is connected to the lower metal layer ALC through the via VB3, and the metal layer ALC is connected to the lower metal layer ALB through the via VB2. In the arrangement region of the pad PD, the metal layer ALD is connected to the lower metal layer ALC through the via VA3, and the metal layer ALC is connected to the lower metal layer ALB through the via VA2.

FIG. 11 is a plan view illustrating layout wiring of the metal layer ALB. In FIG. 11, VDD wiring LBVDD1 is wired along the sides SD1 and SD4, and VDD wiring LBVDD2 is wired along the sides SD2 and SD3. That is, the VDD wiring LBVDD1 and VDD wiring LBVDD2 formed by the metal layer ALB are wired in a substantially ring shape along the inner periphery of the circuit apparatus 10.

FIG. 11 also illustrates an arrangement example of the vias VB2 and VB1 and the vias VA2 and VA1 illustrated in FIGS. 1 and 5. For example, in the arrangement region of the MIM, the metal layer ALC is connected to the lower metal layer ALB through the via VB2, and the metal layer ALB is connected to the lower metal layer ALA through the via VB1. In the arrangement region of the pad PD, the metal layer ALC is connected to the lower metal layer ALB through the via VA2, and the metal layer ALB is connected to the lower metal layer ALA through the via VA1.

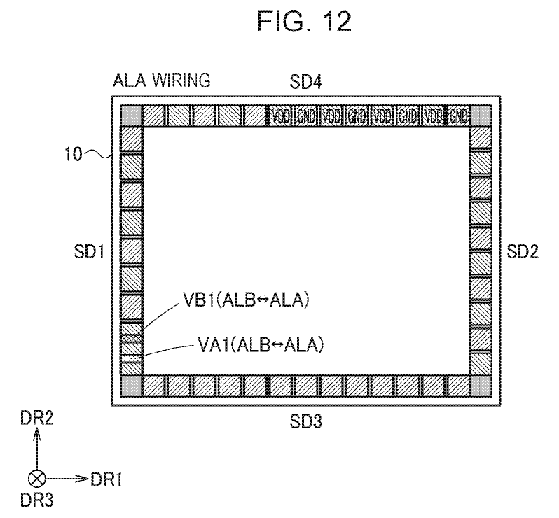

FIG. 12 is a plan view illustrating layout wiring of the metal layer ALA. In the arrangement region of the MIM, the GND wiring and the VDD wiring formed by the metal layer ALA are arranged. In addition, the metal layer ALB is connected to the lower metal layer ALA through the via VB1 in the arrangement region of the MIM, and the metal layer ALB is connected to the lower metal layer ALA through the via VA1 in the arrangement region of the pad PD.

As described above, the circuit apparatus 10 of the present embodiment includes the substrate PSB of the first conductivity type, the well PWL of the first conductivity type provided in the substrate PSB, the well NWL of the second conductivity type provided in the substrate PSB, the pad PD, and the MIM capacitor CM. The MIM capacitor CM includes the electrodes ELA and ELB and the dielectric layer IS provided between the electrode ELA and the electrode ELB. In FIGS. 1 and 5, the first conductivity type is a P-type, and the second conductivity type is an N-type. A modification in which the first conductivity type is an N-type and the second conductivity type is a P-type is also possible. The well PWL is a first well. The well NWL is a second well, the electrode ELA is a first electrode, and the electrode ELB is a second electrode.

In the present embodiment, the well NWL and the pad PD are electrically connected by the first conductive path PT1. One electrode out of the electrode ELA and the electrode ELB of the MIM capacitor CM is electrically connected to the pad PD by the second conductive path PT2, and the other electrode out of the electrode ELA and the electrode ELB is electrically connected to the well PWL by the third conductive path PT3. In FIG. 1, the one electrode connected to the pad PD is the electrode ELA, and the other electrode connected to the well PWL is the electrode ELB. In FIG. 5, the one electrode connected to the pad PD is the electrode ELB, and the other electrode connected to the well PWL is the electrode ELA.

In the present embodiment, as described with reference to FIGS. 1 and 5, the resistance value R2 of the second conductive path PT2 is greater than the resistance value R1 of the first conductive path PT1. In this way, for example, when static charges are accumulated in the substrate PSB or the like, it is possible to suppress a situation in which the charges of the substrate PSB are discharged to the pad PD side via the MIM capacitor CM in the second conductive path PT2 due to the large resistance value R2 of the second conductive path PT2. That is, the charges of the substrate PSB flow to the pad PD side not through the second conductive path PT2 having a large resistance value R2 but through, for example, the first conductive path PT1 having a small resistance value R1. Accordingly, it is possible to prevent a situation in which the dielectric layer IS or the like of the MIM capacitor CM is electrostatically destroyed.

That is, the static charges accumulated in the substrate PSB of the circuit apparatus 10 are discharged through various wiring lines. When a GND pad or the like having the same potential as the substrate PSB is grounded, there is no problem even if the charges are discharged via the pad. However, when the pad PD set to VDD or the like to which a potential different from that of the substrate PSB is supplied is grounded, charges are discharged from the substrate PSB via the pad PD. In this case, in the wiring method of the related art, the charges may be discharged through the insulating film which is the dielectric layer IS of the MIM capacitor CM, and when the charges are discharged through this path, as described in FIG. 3, there is a concern that the insulating film of the MIM capacitor CM may be electrostatically destroyed. In this regard, according to the present embodiment, since the charges of the substrate PSB are discharged from the pad PD without passing through the second conductive path PT2 in which the MIM capacitor CM is provided, it is possible to prevent the dielectric breakdown of the MIM capacitor CM.

In addition, in the present embodiment, the second conductive path PT2 includes the wiring WL1 of the metal layer that is the same layer as or a layer above the metal layer of the electrode ELA. The wiring WL1 is first wiring. For example, in FIG. 1, the second conductive path PT2 includes the wiring WL1 of the metal layer ALD that is the same layer as the metal layer of the electrode ELA. In FIG. 5, the second conductive path PT2 includes the wiring WL1 of the metal layer ALD above the metal layer ALC of the electrode ELA.

In this manner, one electrode of the capacitor CM and the pad PD are electrically connected to each other by the second conductive path PT2 in which the path is detoured through the wiring WL1 of the metal layer that is the same layer as or a layer above the electrode ELA of the capacitor CM. Since the path is detoured through the wiring WL1 in this manner, a parasitic resistance of the wiring WL1 or the like is added, and the resistance value R2 of the second conductive path PT2 can be increased. As the resistance value R2 increases, discharge of charges in the second conductive path PT2 can be suppressed, and dielectric breakdown of the MIM capacitor CM can be prevented.

In addition, one end of the wiring WL1 is electrically connected to one electrode of the MIM capacitor CM, and the other end thereof is electrically connected to the first conductive path PT1. For example, in FIG. 1, one end of the wiring WL1 is connected to the electrode ELA that is one electrode of the MIM capacitor CM, and the other end thereof is connected to the first conductive path PT1. In FIG. 5, one end of the wiring WL1 is connected to the electrode ELB that is one electrode of the MIM capacitor CM, and the other end thereof is connected to the first conductive path PT1.

According to this configuration, one electrode of the capacitor CM and the pad PD are electrically connected to each other by the second conductive path PT2 which is detoured through the path of the wiring WL1 and at least a path segment of the first conductive path PT1. Since the path is detoured through the wiring WL1 and at least a path segment of the first conductive path PT1, the parasitic resistance of the wiring WL1 and the parasitic resistance in the first conductive path PT1 are added, the resistance value R2 of the second conductive path PT2 can be increased, and the dielectric breakdown of the MIM capacitor CM can be prevented.

The second conductive path PT2 includes the wiring WL2 that is the metal layer below the metal layer of the electrode ELA of the capacitor CM. The wiring WL2 is second wiring. For example, in FIGS. 1 and 5, the second conductive path PT2 includes the wiring WL2 of the metal layer ALA below the metal layers ALD and ALC of the electrode ELA. The metal layer of the wiring WL2 may be a layer below the metal layer of the electrode ELA, and may be, for example, the metal layer ALB or ALC, or the like.

In this way, one electrode of the capacitor CM and the pad PD are electrically connected to each other by the second conductive path PT2 in which the path is detoured through the wiring WL2 of the metal layer below the electrode ELA of the capacitor CM. Since the path is detoured through the wiring WL2 in this manner, the parasitic resistance of the wiring WL2 or the like is added, the resistance value R2 of the second conductive path PT2 can be increased, and the dielectric breakdown of the MIM capacitor CM can be prevented.

The metal layer of the wiring WL2 is, for example, the lowermost metal layer ALA as illustrated in FIGS. 1 and 5. That is, the path in the second conductive path PT2 is detoured through the wiring WL2 of the lowermost metal layer ALA among the plurality of metal layers ALE to ALA.

According to this configuration, one electrode of the capacitor CM and the pad PD can be electrically connected to each other by the second conductive path PT2 in which the path is detoured from the metal layer of the one electrode of the MIM capacitor CM to the wiring WL2 of the lowermost metal layer ALA. In this manner, by making the path detour to the wiring WL2 of the lowermost metal layer ALA, it is possible to further increase the resistance value R2 of the second conductive path PT2 and to prevent the dielectric breakdown of the MIM capacitor CM.

The second conductive path PT2 includes the wiring WL1 of the metal layer that is the same layer as or a layer above the metal layer of the electrode ELA and the wiring WL2 of the metal layer below the metal layer of the electrode ELA. For example, the second conductive path PT2 includes the wiring WL1 of the metal layer ALD that is the same layer as the electrode ELA and the wiring WL2 of the metal layer ALA below the electrode ELA in FIG. 1, and includes the wiring WL1 of the metal layer ALD above the metal layer ALC of the electrode ELA and the wiring WL2 of the metal layer ALA below the metal layer ALC of the electrode ELA in FIG. 5. The wiring WL1 and the wiring WL2 are electrically connected to each other through a via connecting metal layers. For example, in FIGS. 1 and 5, the wiring WL1 and the wiring WL2 are electrically connected to each other through the vias VB3, VB2, and VB1.

In this manner, one electrode of the capacitor CM and the pad PD can be electrically connected to each other by the second conductive path PT2 which is a path detoured through the wiring WL1, the wiring WL2, and the vias VB3, VB2, and VB1 which connect the wiring WL1 and the wiring WL2. Since the path is detoured through the wiring WL1, the vias VB1, VB2, and VB3, and the wiring WL2 in this way, parasitic resistances of the wiring WL1 and wiring WL2, the vias VB1, VB2, and VB3, and the like are added, and thus it is possible to increase the resistance value R2 of the second conductive path PT2.

The substrate PSB and the well PWL are set to a potential of a first power supply, and the pad PD is a pad to which a potential different from the potential of the first power supply is supplied. For example, when the conductivity type of the substrate PSB and the well PWL is the P-type, the substrate PSB and the well PWL are set to, for example, the potential of GND which is the first power supply on the low potential side. The pad PD is a pad to which, for example, a potential at VDD or the like different from the first power supply is supplied during the operation of the circuit apparatus 10. The conductivity type of the substrate and the well may be an N-type, and in this case, the first power supply is a power supply on the high potential side.

In this way, the MIM capacitor CM can be used as a capacitor for stabilizing a potential provided between the well PWL and the pad PD. When charges are accumulated in the substrate PSB, if the pad PD is set to, for example, the potential of the first power supply, the accumulated charges can be discharged through the first conductive path PT1 instead of the second conductive path PT2 passing through the capacitor CM.

The first conductive path PT1 includes a plurality of vias each connecting metal layers. For example, in FIGS. 1 and 5, the first conductive path PT1 includes a plurality of vias VA1, VA2, VA3, and VA4 connecting the metal layers ALA and ALB, ALB and ALC, ALC and ALD, and ALD and ALE, respectively.

With this configuration, when charges are accumulated in the substrate PSB, the accumulated charges can be discharged from the pad PD through the vias VA1, VA2, VA3, and VA4 of the first conductive path PT1.

As illustrated in FIGS. 1 and 5, the circuit apparatus 10 of the present embodiment includes the substrate PSB, the well PWL, the well NWL, the pad PD, and the MIM capacitor CM. In addition, the well NWL and the pad PD are electrically connected by the first conductive path PT1, one electrode out of the electrode ELA and the electrode ELB and the pad PD are electrically connected by the second conductive path PT2, and the other electrode out of the electrode ELA and the electrode ELB and the well PWL are electrically connected by the third conductive path PT3. The second conductive path PT2 includes the wiring WL1 of the metal layer that is the same layer as or a layer above the metal layer of the electrode ELA and the wiring WL2 of the metal layer below the metal layer of the electrode ELA.

In this way, one electrode of the capacitor CM and the pad PD are electrically connected to each other by the second conductive path PT2 in which the path is detoured through the wiring WL1 of the metal layer that is the same layer as or a layer above the electrode ELA of the capacitor CM and the wiring WL2 of the metal layer below the electrode ELA. Since the path is detoured through the wiring WL1 and wiring WL2 in this manner, parasitic resistances of the wiring WL1 and wiring WL2 and the like are added, discharge of charges in the second conductive path PT2 can be suppressed, and dielectric breakdown of the MIM capacitor CM can be prevented.

The circuit apparatus 10 of the present embodiment has a plurality of wiring layers formed by metal layers, and the plurality of wiring layers are four or more layers, typically four or five layers. For example, in FIGS. 1 and 5, the five metal layers ALA to ALE are provided as the plurality of wiring layers. These wiring layers are used for signal transmission and power supply, and the number of layers may be four or more in order to realize miniaturization based on three-dimensional crossing of wiring lines. An upper wiring layer is used for long-distance signal transmission and power supply, and a lower wiring layer is used for short-distance signal transmission and power supply. For example, the wiring layer on a transistor side among the plurality of wiring layers is used as local wiring and connects a source, a drain, and a gate of the transistor. A wiring layer above the local wiring connects the local wiring and global wiring as intermediate wiring and is used for signal transmission and power supply for an intermediate distance. The intermediate wiring may include a wiring layer mainly including wiring extending in a first direction and a wiring layer mainly including wiring extending in a second direction intersecting the first direction. A layer above the intermediate wiring is used to perform long-distance signal transmission as the global wiring. For example, the intermediate wiring may be wiring within a circuit block, and the global wiring may be wiring between circuit blocks. The GND wiring may be formed in two adjacent layers of the four layers, and the VDD wiring may be formed in the other two different layers. By forming the power supply wiring in a plurality of layers, the power supply can be stabilized. An inductor may be formed in an uppermost wiring layer, and the uppermost wiring layer may be thicker than the other wiring layers.

### 2. Detailed example of circuit apparatus

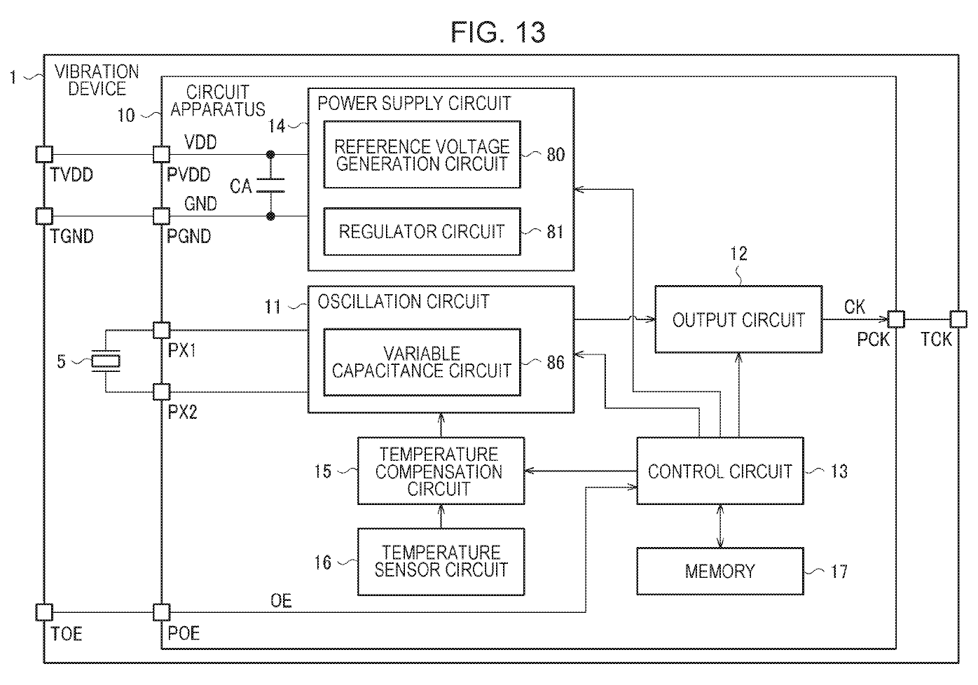

FIG. 13 illustrates a detailed configuration example of the circuit apparatus 10 of the present embodiment. The circuit apparatus 10 includes an oscillation circuit 11 and an output circuit 12. The circuit apparatus 10 may also include a control circuit 13, a power supply circuit 14, a temperature compensation circuit 15, a temperature sensor circuit 16, and a memory 17. The vibration device 1 of the present embodiment includes the vibration element 5 and the circuit apparatus 10, and the vibration element 5 and the circuit apparatus 10 are electrically connected to each other. The configurations of the circuit apparatus 10 and the vibration device 1 are not limited to the configuration of FIG. 13, and various modifications can be made such as omitting some of the components, adding other components, or replacing some of the components with other components. For example, in FIG. 13, a clock signal generation circuit such as a PLL circuit that multiplies a clock frequency may be provided between the oscillation circuit 11 and the output circuit 12. Furthermore, FIG. 13 illustrates a configuration example in a case where the vibration device 1 is an oscillator that generates a clock signal CK, but the vibration device 1 may be a device such as a gyro sensor or an acceleration sensor.

As illustrated in FIG. 13, the vibration device 1 includes terminals TCK, TOE, TVDD, and TGND. The terminal TCK is a terminal for outputting the clock signal CK, and the terminal TOE is a terminal for inputting an output enable signal OE. The terminal TVDD is supplied with the power supply voltage VDD, and the terminal TGND is supplied with the ground voltage GND. Here, GND can also be referred to as VSS. For example, VDD corresponds to a high-potential-side power supply voltage, and GND corresponds to a low-potential-side power supply voltage. These terminals TCK, TOE, TVDD, and TGND correspond to external connection terminals 91 and 92 in FIG. 14 to be described later. For example, in the case of the vibration device 1 having four terminals, four terminals are provided as the external connection terminals 91 and 92. The number of terminals of the vibration device 1 is not limited thereto, and may be greater than or equal to four or may be less than or equal to four. The circuit apparatus 10 includes pads PCK, POE, PVDD, PGND, PX1, and PX2. A pad is a terminal of the circuit apparatus 10. The pads PCK, POE, PVDD, and PGND are electrically connected to the terminals TCK, TOE, TVDD, and TGND of the vibration device 1, respectively.

The oscillation circuit 11 is a circuit that oscillates the vibration element 5. For example, the oscillation circuit 11 is electrically connected to the vibration element 5 via the pads PX1 and PX2 and generates an oscillation signal by oscillating the vibration element 5. For example, the oscillation circuit 11 can be realized by a drive circuit for oscillation provided between the pad PX1 and the pad PX2 and a passive element such as a capacitor or a resistor. The drive circuit can be implemented by, for example, a CMOS inverter circuit or a bipolar transistor. The drive circuit is a core circuit of the oscillation circuit 11, and the drive circuit drives the vibration element 5 with voltage or current to oscillate the vibration element 5. For example, various types of oscillation circuits such as an inverter type, a Pierce type, a Colpitts type, and a Hartley type can be used as the oscillation circuit 11. In addition, for example, a variable capacitance circuit 86 is provided in the oscillation circuit 11, and an oscillation frequency can be adjusted by adjusting a capacitance of the variable capacitance circuit 86. The variable capacitance circuit 86 can be realized by, for example, a variable capacitance element such as a varactor. Alternatively, the variable capacitance circuit 86 may be realized by a capacitor array and a switch array connected to the capacitor array. For example, the variable capacitance circuit 86 may be constituted by a capacitor array having a plurality of capacitors capacitance values of which are weighted in a binary manner, and a switch array having a plurality of switches each of which turns on and off a connection between each capacitor of the capacitor array and the pad PX1 or the pad PX2.

The output circuit 12 outputs the clock signal CK based on the oscillation signal. For example, the output circuit 12 buffers an oscillation clock signal based on the oscillation signal and outputs the buffered oscillation clock signal to the pad PCK as the clock signal CK. Then, the clock signal CK is output to the outside via the terminal TCK of the vibration device 1. For example, the output circuit 12 outputs the clock signal CK in a single-ended CMOS signal format. For example, when the output enable signal OE input from the terminal TOE via the pad POE is active, the output circuit 12 outputs the clock signal CK under control of the control circuit 13. On the other hand, when the output enable signal OE is inactive, the output circuit 12 sets the clock signal CK to a fixed voltage level such as a low level, for example. The output circuit 12 may output a differential clock signal in a signal format such as low voltage differential signaling (LVDS), positive emitter coupled logic (PECL), high speed current steering logic (HCSL), or differential complementary metal oxide semiconductor (CMOS). In this case, two clock terminals and pads for a positive polarity and a negative polarity of the differential clock signal may be provided, and the vibration device 1 is, for example, a six-terminal oscillator.

The control circuit 13 is a logic circuit and performs various control processes. For example, the control circuit 13 controls the whole circuit apparatus 10 or controls an operation sequence of the circuit apparatus 10. The control circuit 13 may control the oscillation circuit 11, the power supply circuit 14, the temperature compensation circuit 15, the memory 17, or the like. The control circuit 13 can be implemented by, for example, a circuit of an application specific integrated circuit (ASIC) through autonomous arranging and routing, such as a gate array.

The power supply circuit 14 is supplied with VDD that is a power supply voltage from the terminal TVDD via the pad PVDD and is supplied with GND that is a ground voltage from the terminal TGND via the pad PGND. The power supply circuit 14 supplies a power supply voltage for each internal circuit of the circuit apparatus 10 to each internal circuit.

The power supply circuit 14 includes a reference voltage generation circuit 80, and the reference voltage generation circuit 80 generates a reference voltage used in the circuit apparatus 10. The power supply circuit 14 also includes a regulator circuit 81, and the regulator circuit 81 generates a regulated voltage used in the circuit apparatus 10. The regulated voltage is supplied to each circuit of the circuit apparatus 10 such as the oscillation circuit 11, the output circuit 12, and the control circuit 13.

The temperature compensation circuit 15 performs temperature compensation of an oscillation frequency of the oscillation circuit 11. Then, the output circuit 12 outputs the clock signal CK based on the temperature-compensated oscillation signal. Specifically, the temperature compensation circuit 15 performs temperature compensation based on a temperature detection signal from the temperature sensor circuit 16. For example, the temperature compensation circuit 15 performs temperature compensation of the oscillation frequency of the oscillation circuit 11 by generating a temperature compensation voltage based on the temperature detection voltage from the temperature sensor circuit 16 and outputting the generated temperature compensation voltage to the oscillation circuit 11. For example, the temperature compensation circuit 15 performs temperature compensation by outputting a temperature compensation voltage serving as a capacitance control voltage of the variable capacitance circuit 86 to the variable capacitance circuit 86 included in the oscillation circuit 11. In this case, the variable capacitance circuit 86 of the oscillation circuit 11 is realized by a variable capacitance element such as a varactor. The temperature compensation is a process of suppressing and compensating for a variation in the oscillation frequency due to a temperature variation. For example, the temperature compensation circuit 15 performs analog temperature compensation by polynomial approximation. For example, when a temperature compensation voltage for compensating for frequency-temperature characteristics of the vibration element 5 is approximated by a polynomial, the temperature compensation circuit 15 performs analog temperature compensation based on coefficient information of the polynomial.

Furthermore, the temperature compensation circuit 15 may perform digital temperature compensation. In this case, the temperature compensation circuit 15 is realized by, for example, a logic circuit. Specifically, the temperature compensation circuit 15 performs a digital temperature compensation process based on temperature detection data which is a temperature detection signal of the temperature sensor circuit 16. For example, the temperature compensation circuit 15 obtains frequency adjustment data based on the temperature detection data. Then, a capacitance value of the variable capacitance circuit 86 of the oscillation circuit 11 is adjusted based on the obtained frequency adjustment data, and thus the temperature compensation process of the oscillation frequency of the oscillation circuit 11 is realized. In this case, the variable capacitance circuit 86 of the oscillation circuit 11 is realized by a capacitor array including a plurality of binary-weighted capacitors and a switch array. In addition, the memory 17 stores a lookup table representing a correspondence between the temperature detection data and the frequency adjustment data, and the temperature compensation circuit 15 performs a temperature compensation process of obtaining the frequency adjustment data based on the temperature data by using the lookup table read from the memory 17 by the control circuit 13.

The temperature sensor circuit 16 is a sensor circuit that detects a temperature. The temperature sensor circuit 16 outputs a temperature-dependent voltage that changes in accordance with a temperature in an environment as a temperature detection voltage. For example, the temperature sensor circuit 16 generates the temperature detection voltage by using a circuit element having temperature dependency. Specifically, the temperature sensor circuit 16 outputs the temperature detection voltage a voltage value of which changes depending on the temperature by using a temperature dependency of a forward voltage of the PN junction. As the forward voltage of the PN junction, for example, a base-emitter voltage of a bipolar transistor or the like can be used.

In addition, in a case where the digital temperature compensation process is performed, the temperature sensor circuit 16 measures a temperature such as an environmental temperature and outputs a result thereof as the temperature detection data. The temperature detection data is, for example, data that monotonously increases or monotonously decreases with respect to the temperature. As the temperature sensor circuit 16 in this case, a temperature sensor circuit using a phenomenon that an oscillation frequency of a ring oscillator has temperature dependency can be used.

The memory 17 stores various types of information used in the circuit apparatus 10. The memory 17 is, for example, a nonvolatile memory or the like. The nonvolatile memory is an electrically erasable programmable read-only memory (EEPROM) such as a floating gate avalanche injection metal oxide semiconductor (FAMOS) memory or a metal-oxide-nitride-oxide-silicon (MONOS) memory but is not limited thereto, and may be a one time programmable (OTP) memory, a fuse type ROM, or the like. Alternatively, the memory 17 may be realized by a volatile memory such as a RAM.

In the present embodiment, as illustrated in FIG. 13, the capacitor CA is provided between the VDD pad PVDD and the GND pad PGND. The pad PVDD corresponds to the pad PD in FIGS. 1, 5, and 6, and the pad PGND corresponds to the pad PD2 in FIG. 6. The capacitor CA is a capacitor used as a bypass condenser for power supply stabilization. The MIM capacitor CM is used as the power stabilizing capacitor CA.

In the circuit apparatus 10, VDD is supplied to the pad PVDD, and GND is supplied to the pad PGND during operation. On the other hand, at the time of manufacturing the vibration device 1 or the like, charges may be accumulated in the substrate PSB of the circuit apparatus 10 due to static electricity. Then, for example, when the terminal TVDD of the vibration device 1 comes into contact with an object having a potential of GND in a state where the charges are accumulated in the substrate PSB as described above, a situation in which the accumulated charges are discharged to GND via the pad PVDD and the terminal TVDD occurs. Even in this case, in the present embodiment, as described in FIGS. 1, 4, and 5, the charges are discharged through the first conductive path PT1 instead of the second conductive path PT2, and it is possible to prevent electrostatic breakdown of the capacitor CA constituted by the MIM capacitor CM.

### 3. Vibration device

FIG. 14 is a cross-sectional view illustrating a configuration example of the vibration device 1 according to the present embodiment. As illustrated in FIG. 14, the vibration device 1 according to the present embodiment includes a base 2, a lid 3, and a vibration element 5. In addition, the vibration device 1 can include a redistribution layer 8 and external connection terminals 91 and 92. In each drawing described in the present embodiment, an X axis, a Y axis, and a Z axis are illustrated as three axes orthogonal to each other. A direction along the X axis is referred to as an X axis direction or a direction DR1, a direction along the Y axis is referred to as a Y axis direction or a direction DR2, and a direction along the Z axis is referred to as a Z axis direction or a direction DR3. In addition, a tip side of an arrow in each axial direction is referred to as a "plus side", a base side of the arrow is referred to as a "minus side", a plus side in the Z axis direction is referred to as "up", and a minus side in the Z axis direction is referred to as "down". For example, the Z axis direction is along a vertical direction, and an XY plane is along a horizontal plane. FIG. 14 is a cross-sectional view of the vibration device 1 in a cross-sectional view from the direction DR2 which is the Y axis direction.

The vibration device 1 is, for example, an oscillator. Specifically, the vibration device 1 is, for example, an oscillator such as a temperature compensated crystal oscillator (TCXO), an oven controlled crystal oscillator (OCXO), a voltage controlled crystal oscillator (VCXO), a crystal oscillator without a temperature compensation function (SPXO), a surface acoustic wave (SAW) oscillator, a voltage controlled type SAW oscillator, or a micro electro mechanical systems (MEMS) oscillator. The MEMS oscillator can be realized by a MEMS vibration element in which a piezoelectric film and an electrode are arranged on a substrate such as a silicon substrate. However, the vibration device 1 may be an inertial sensor such as an acceleration sensor or an angular velocity sensor, a force sensor such as an inclination sensor, or the like.

The base 2 includes the substrate 20. The substrate 20 is a semiconductor substrate, for example, a silicon substrate. The substrate 20 has a first surface 21 and a second surface 22 opposite to the first surface 21. The first surface 21 is, for example, an upper surface of the substrate 20, and the second surface 22 is, for example, a lower surface of the substrate 20. The first surface 21 and the second surface 22 of the substrate 20 are also a first surface and a second surface of the base 2. The first surface 21 and the second surface 22 of the substrate 20 are surfaces along the XY plane and are surfaces orthogonal to the Z axis. That is, the first surface 21 and the second surface 22 are surfaces along the direction DR1 and the direction DR2 and are surfaces orthogonal to the direction DR3. It should be noted that the term "orthogonal" includes not only a case of intersecting at 90° but also a case of intersecting at an angle slightly inclined from 90°.

An integrated circuit 19 is provided to the substrate 20 of the base 2. The integrated circuit 19, which is a semiconductor circuit, is formed on the second surface 22 of the substrate 20. A modification is possible in which the integrated circuit 19 is provided on the first surface 21 of the substrate 20. The integrated circuit 19 is constituted by a plurality of circuit elements. The circuit element is, for example, an active element such as a transistor or a diode, or a passive element such as a capacitance element, a resistance element, or an inductor element. The transistor is a CMOS transistor, a bipolar transistor, or the like. Specifically, the integrated circuit 19 is constituted by a plurality of circuit blocks each including a plurality of circuit elements. The integrated circuit 19 is formed including a diffusion region which is an impurity region formed by doping the substrate 20 with an impurity, and a wiring layer in which a metal layer and an insulating layer are stacked. A source region and a drain region of the transistor which is the circuit element of the integrated circuit 19 are formed by the diffusion region, and wiring which connects the circuit elements is formed by the wiring region.

The substrate 20 in FIG. 14 corresponds to the substrate PSB in FIGS. 1 and 5. Furthermore, the circuit apparatus 10 of FIGS. 1 and 5 is realized by providing the integrated circuit 19 to the substrate 20.

A through electrode 40 is also provided in the substrate 20 of the base 2. The through electrode 40 is made of a conductive material that penetrates the first surface 21 and the second surface 22 of the substrate 20. For example, the through electrode 40 is formed by forming a through hole in the substrate 20 and filling the through hole with a conductive material. The conductive material may be a metal such as copper, conductive polysilicon, or the like. The conductive polysilicon is, for example, polysilicon doped with an impurity such as phosphorus (P), boron (B), or arsenic (As) to provide conductivity. When polysilicon is used as the conductive material, it is possible to realize the through electrode 40 having sufficient resistance to heat applied in the process of forming the integrated circuit 19.

One end of the through electrode 40 is electrically connected to the vibration element 5 via a conductive bonding portion 60. In FIG. 14, the conductive bonding portion 60 is realized by a bump or the like, one end of which is electrically connected to the vibration element 5 and the other end of which is electrically connected to the through electrode 40. The bump is a conductive bonding member and is specifically a gold bump, a silver bump, a copper bump, a solder bump, a resin core bump, or the like. As the conductive bonding portion 60, a conductive adhesive in which a conductive filler such as a silver filler is dispersed in various adhesives such as a polyimide-based adhesive, an epoxy-based adhesive, a silicone-based adhesive, or an acrylic-based adhesive may be used. The other end of the through electrode 40 is electrically connected to the integrated circuit 19. Specifically, the other end of the through electrode 40 is connected to the circuit element of the integrated circuit 19 via a contact pad formed in the integrated circuit 19. With this configuration, the vibration element 5 and the integrated circuit 19 can be electrically connected to each other via the through electrode 40.

The lid 3 is bonded to the base 2 at bonding portions 36 and 37. The base 2 is constituted by, for example, a semiconductor substrate such as a silicon substrate. Specifically, the lid 3 is provided with a recessed portion 30 for accommodating the vibration element 5 and has side wall portions 32 and 33 around the recessed portion 30. The side wall portions 32 and 33 are, for example, wall portions provided around the recessed portion 30 in plan view in the direction DR3 which is the Z axis direction. End surfaces 34 and 35 of the side wall portions 32 and 33 are bonded to the first surface 21 of the base 2 at the bonding portions 36 and 37. The bonding portions 36 and 37 are formed by, for example, a metal film such as a gold or copper film. The base 2 and the lid 3 are bonded to each other by applying a pressure based on a weight described later to sections of the bonding portions 36 and 37 of the metal film such as the gold film. A bonding method of the base 2 and the lid 3 by the bonding portions 36 and 37 is not limited to this, and various bonding methods such as direct bonding are possible. An airtight accommodation space SP is formed by the base 2 and the lid 3 which is a lid body, and the vibration element 5 is accommodated in the accommodation space SP. The accommodation space SP corresponds to the recessed portion 30 of the lid 3. The accommodation space SP is hermetically sealed, and an inside of the accommodation space SP is, for example, in a decompressed state. Thus, it is possible to stably drive the vibration element 5. A state in the accommodation space SP is not limited to the decompressed state, and for example, the accommodation space SP may be filled with an inert gas atmosphere.

In the present embodiment, both the base 2 and the lid 3 are formed by, for example, a semiconductor substrate such as a silicon substrate. Accordingly, it is possible to make thermal expansion coefficients of the base 2 and the lid 3 equal to each other, and it is possible to suppress generation of thermal stress due to thermal expansion, so that the vibration device 1 having excellent characteristics can be realized. In addition, since the vibration device 1 can be formed through a semiconductor process, it is possible to efficiently manufacture the vibration device 1 with high accuracy, and it is possible to achieve miniaturization of the vibration device 1. The semiconductor substrate constituting the base 2 and the lid 3 is not limited to a silicon substrate and may be a semiconductor substrate made of Ge, GaP, GaAs, InP, or the like.

The vibration element 5 is an element that generates mechanical vibration by an electrical signal. The vibration element 5 is electrically connected to the integrated circuit 19 (the circuit apparatus 10). For example, the vibration element 5 is arranged on the first surface 21 side of the substrate 20. Specifically, the vibration element 5 is arranged at a position separated from the first surface 21 of the substrate 20 by a predetermined separation distance. More specifically, the vibration element 5 is fixed to the first surface 21 of the substrate 20 via, for example, the conductive bonding portion 60.

For example, the vibration element 5 includes a vibration substrate and an electrode arranged on a surface of the vibration substrate. The vibration substrate has a thickness-shear vibration mode and is formed by, for example, an AT-cut quartz crystal substrate. Since the AT-cut quartz crystal substrate has third order frequency-temperature characteristics, the vibration element 5 having excellent temperature characteristics is obtained. The electrode includes an excitation electrode arranged on the upper surface of the vibration substrate and an excitation electrode arranged on the lower surface so as to face the excitation electrode.

The configuration of the vibration element 5 is not limited to the above-described configuration. For example, the vibration element 5 may have a mesa shape in which a vibration region interposed between the two excitation electrodes protrudes from a periphery thereof, or may have an inverted mesa shape in which the vibration region is recessed from the periphery thereof. In addition, bevel processing for grinding the periphery of the vibration substrate or convex processing for shaping the upper surface and the lower surface to be convex curved surfaces may be performed. In addition, the vibration element 5 is not limited to an element that vibrates in the thickness-shear vibration mode. For example, the vibration element 5 may be a tuning fork type vibration element in which a plurality of vibrating arms flexurally vibrate in an in-plane direction, a tuning fork type vibration element in which a plurality of vibrating arms flexurally vibrate in an out-of-plane direction, a gyro sensor element which includes a drive arm which performs drive vibration and a detection arm which performs detection vibration to detect an angular velocity, or an acceleration sensor element including a detection unit which detects acceleration. In addition, the vibration substrate is not limited to the vibration substrate formed by the AT-cut quartz crystal substrate and may be formed by a quartz crystal substrate other than the AT-cut quartz crystal substrate. For example, the vibration substrate may be formed by an X-cut quartz crystal substrate, a Y-cut quartz crystal substrate, a Z-cut quartz crystal substrate, a BT-cut quartz crystal substrate, an SC-cut quartz crystal substrate, an ST-cut quartz crystal substrate, or the like. In addition, in the present embodiment, the vibration substrate is formed of quartz crystal but is not limited thereto. The vibration substrate may be formed of, for example, a piezoelectric single crystal such as lithium niobate, lithium tantalate, lithium tetraborate, potassium niobate, or gallium phosphate or may be formed of a piezoelectric single crystal other than these. In addition, the vibration element 5 is not limited to a piezoelectric drive type vibration element and may be an electrostatic drive type vibration element using an electrostatic force.

The external connection terminals 91 and 92 are provided on the second surface 22 side of the substrate 20 via an insulating layer or the like. The insulating layer is, for example, an insulating layer constituting the redistribution layer 8.

The redistribution layer 8 is provided on the second surface 22 side of the substrate 20 and includes an insulating layer and wiring for redistribution wiring. The insulating layer is realized by, for example, a resin layer made of polyimide or the like, and the wiring is realized by, for example, metal wiring using a copper foil or the like. The insulating layer needs to have heat resistance that can withstand soldering at the time of mounting the vibration device 1, and polyimide may be used. Furthermore, as the material of the wiring, a metal material such as silver may be used instead of copper. By providing the redistribution layer 8, contact pads formed on the integrated circuit 19 can be electrically connected to the external connection terminals 91 and 92. Then, the external connection terminals 91 and 92 of the vibration device 1 are mounted to be connected to terminals or wiring lines of a circuit substrate or the like on which the vibration device 1 is mounted, and thus it is possible to incorporate the vibration device 1 into electronic equipment. In addition, by providing the redistribution layer 8 described above, it is possible to mechanically protect a section corresponding to the integrated circuit 19 and to thermally protect the integrated circuit 19 and the like from heat in a soldering process when the vibration device 1 is mounted.

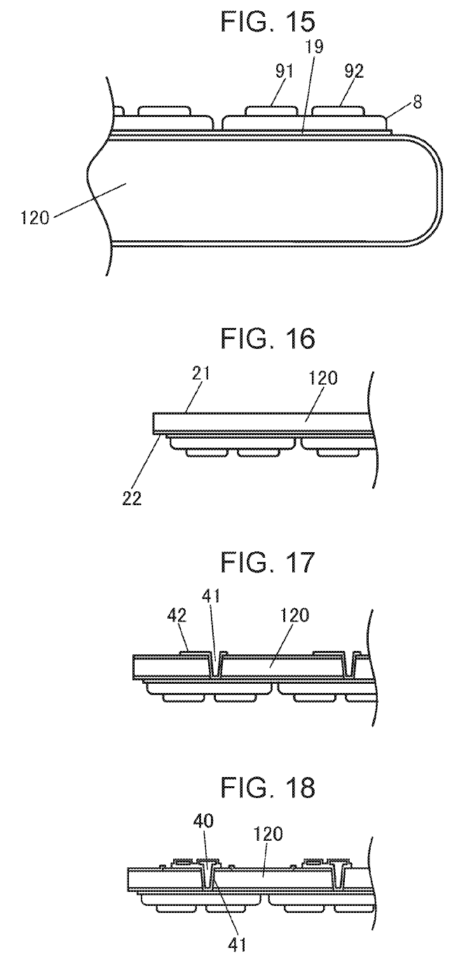

Next, an example of a manufacturing flow of the vibration device 1 will be described with reference to FIGS. 15 to 21. First, as illustrated in FIG. 15, the integrated circuit 19, the redistribution layer 8, and the external connection terminals 91 and 92 are formed on a first semiconductor wafer 120. Then, as illustrated in FIG. 16, the first surface 21 side of the first semiconductor wafer 120 is ground and polished to have a thickness of, for example, about 60 μm to 80 μm. Next, as illustrated in FIG. 17, a through hole 41 (through silicon via) is formed in the first semiconductor wafer 120, and an insulating film 42 made of, for example, silicon oxide (SiO₂) is formed on the inner surface of the through hole 41. Then, as illustrated in FIG. 18, the through electrode 40 is formed in the through hole 41.

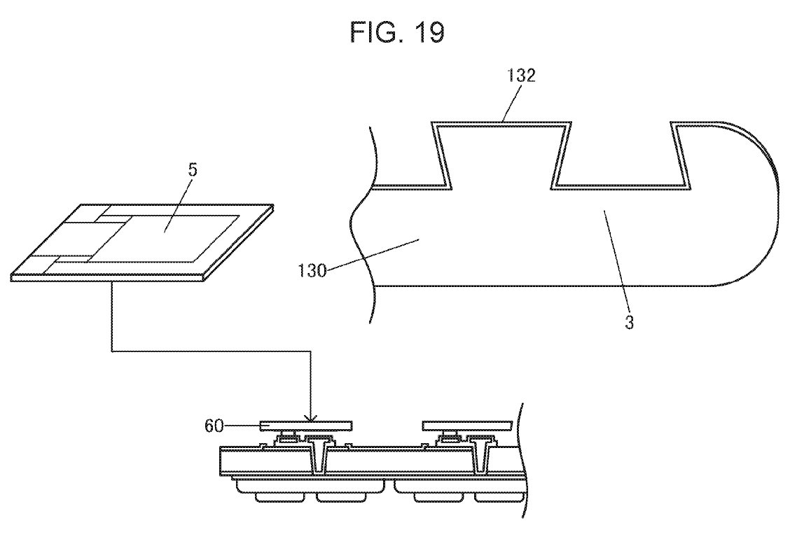

Next, as illustrated in FIG. 19, the vibration element 5 is connected to the bonding portion 60. Accordingly, the vibration element 5 and the integrated circuit 19 are electrically connected to each other. In addition, a second semiconductor wafer 130 for forming the lid 3 is prepared, and a metal film 132 which is a bonding film made of a material such as gold is formed on a surface on a recessed portion side of the second semiconductor wafer 130.

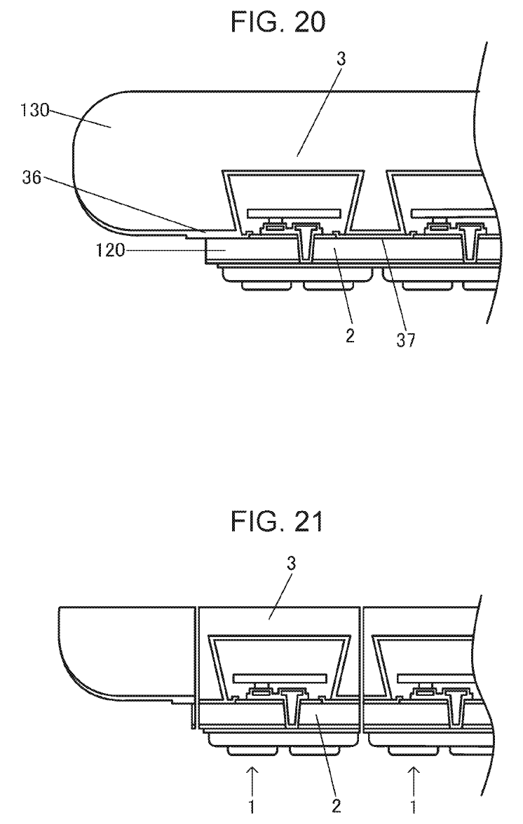

Next, as illustrated in FIG. 20, the second semiconductor wafer 130 in which the lid 3 is formed is bonded to the first semiconductor wafer 120 in which the base 2 is formed, by stress application via the bonding portions 36 and 37. This bonding is performed, for example, in a vacuum atmosphere. The bonding portions 36 and 37 are bonding portions formed by a metal film 132 made of gold or the like illustrated in FIG. 19. A force applied by load when the second semiconductor wafer 130 is bonded to the first semiconductor wafer 120 is, for example, 10 tons or more and is about 20 tons as an example.

Next, as illustrated in FIG. 21, after grinding, dicing for dividing the vibration device 1 into individual pieces is performed by a dicing saw or the like. As described above, a large number of vibration devices 1 can be singulated from the first semiconductor wafer 120 and the second semiconductor wafer 130. A length of a long side in plan view of the vibration devices 1 is, for example, about 1.2 mm to 1.0 mm, and a length of a short side is, for example, about 1.0 mm to 0.8 mm. A width of a dicing blade is, for example, about 20 μm, and a width of each of the bonding portions 36 and 37 of the vibration device 1 is, for example, about 30 μm to 100 μm and is about 60 μm as an example.

As described above, the circuit apparatus 10 of the present embodiment is realized by providing the integrated circuit 19 to the substrate 20. The vibration device 1 according to the present embodiment includes the circuit apparatus 10 (the integrated circuit 19 and the substrate 20), the through electrode 40 provided in the substrate 20 of the circuit apparatus 10, the vibration element 5 electrically connected to the through electrode 40, and the lid 3 that accommodates the vibration element 5 together with the substrate 20. Specifically, the vibration device 1 according to the present embodiment includes the base 2 including the substrate 20 which has the first surface 21 and the second surface 22 and in which, for example, the integrated circuit 19 is arranged on the second surface 22, and the vibration element 5 which is electrically connected to the integrated circuit 19. The vibration device 1 also includes the lid 3 which has the side wall portions 32 and 33 around the recessed portion 30 accommodating the vibration element 5 and in which the end surfaces 34 and 35 of the side wall portions 32 and 33 are bonded to the first surface 21 at the bonding portions 36 and 37.

For example, a vibration device in related art has a configuration in which an IC chip and a crystal vibration element are incorporated in a ceramic package. In contrast, in the vibration device 1 of the wafer level packaging (WLP) described in FIGS. 14 to 21, since the IC itself is packaged, it is possible to maximize an area of the integrated circuit 19 which is the IC, and it is possible to realize a small and highly functional oscillator or the like. For example, in a vibration device of a ceramic package type, the area of the IC in plan view is, for example, 50% to 60% or less of the area of the package of the vibration device. On the other hand, according to the vibration device 1 of the WLP, it is possible to make the area of the integrated circuit 19 greater than, for example, 50% to 60% of the area of the base 2. Thus, it is possible to provide a circuit for making the vibration device 1 more highly functional in the integrated circuit 19.

In the vibration device 1 of the WLP as illustrated in FIG. 14, charges may be accumulated in the substrate 20 via the lid 3 or the like in the manufacturing process or the like. When an external connection terminal which is connected to, for example, the VDD pad out of the external connection terminals 91 and 92 comes into contact with an object having the GND potential, a situation may occur that the charges of the substrate 20 are discharged.

In this regard, in the present embodiment, as described with reference to FIGS. 1 and 5, the resistance value of the second conductive path PT2 which connects the electrode of the MIM capacitor CM and the pad is increased. In this way, since the charges of the substrate 20 are discharged through the first conductive path PT1 instead of the second conductive path PT2 passing through the MIM capacitor CM, it is possible to prevent the occurrence of electrostatic breakdown of the MIM capacitor CM.

As described above, the circuit apparatus 10 of the present embodiment includes the substrate of the first conductivity type, the first well of the first conductivity type provided in the substrate, the second well of the second conductivity type provided in the substrate, the pad, and the MIM capacitor having the first electrode, the second electrode, and the dielectric layer provided between the first electrode and the second electrode. Furthermore, the second well and the pad are electrically connected by the first conductive path, one electrode out of the first electrode and the second electrode and the pad are electrically connected by the second conductive path, and the other electrode out of the first electrode and the second electrode and the first well are electrically connected by the third conductive path. The resistance value of the second conductive path is greater than the resistance value of the first conductive path.

According to the present embodiment, the second well and the pad are connected by the first conductive path, and one electrode of the MIM capacitor and the pad are connected by the second conductive path PT2. The resistance value of the second conductive path is greater than the resistance value of the first conductive path. With this configuration, the charges accumulated in the substrate flow to the pad side via the first conductive path having a small resistance value, not via the second conductive path having a large resistance value. Accordingly, it is possible to prevent a situation in which the MIM capacitor is electrostatically destroyed or the like.

Furthermore, in the present embodiment, the second conductive path may include the first wiring of the metal layer that is the same layer as or a layer above the metal layer of the first electrode.

According to this configuration, one electrode of the capacitor and the pad are electrically connected to each other by the second conductive path in which the path is detoured through the first wiring of the metal layer that is the same layer as or a layer above the first electrode of the capacitor, and it is possible to increase the resistance value of the second conductive path.

In the present embodiment, one end of the first wiring may be electrically connected to the one electrode, and the other end of the first wiring may be electrically connected to the first conductive path.

According to this configuration, one electrode of the capacitor and the pad are electrically connected to each other by the second conductive path which is detoured through the path of the first wiring and at least a path segment of the first conductive path, and thus it is possible to increase the resistance value of the second conductive path.

Furthermore, in the present embodiment, the second conductive path may include the second wiring of the metal layer below the metal layer of the first electrode.

According to this configuration, one electrode of the capacitor and the pad are electrically connected to each other by the second conductive path in which the path is detoured through the second wiring of the metal layer below the first electrode of the capacitor, and thus it is possible to increase the resistance value of the second conductive path.

Furthermore, in the present embodiment, the metal layer of the second wiring may be the lowermost metal layer.

According to this configuration, it is possible to electrically connect one electrode of the capacitor and the pad by the second conductive path in which the path is detoured from the metal layer of the one electrode of the capacitor to the second wiring of the lowermost metal layer.

In addition, in the present embodiment, the second conductive path may include the first wiring of the metal layer that is the same layer as or a layer above the metal layer of the first electrode and the second wiring of the metal layer below the metal layer of the first electrode, and the first wiring and the second wiring may be electrically connected to each other through a via connecting metal layers.

According to this configuration, one electrode of the capacitor and the pad can be electrically connected to each other by the second conductive path in which the path is detoured through the first wiring, the second wiring, and the via which connects the first wiring and the second wiring.

Furthermore, in the present embodiment, the substrate and the first well may be set to a potential of the first power supply, and the pad may be a pad to which a potential different from the potential of the first power supply is supplied.

With this configuration, in a case where the pad is set to, for example, the potential of the first power supply when the charges are accumulated in the substrate, it is possible to discharge the accumulated charges through the first conductive path instead of the second conductive path passing through the capacitor.

In addition, in the present embodiment, the first conductive path may include a plurality of vias which connect metal layers.

With this configuration, when charges are accumulated in the substrate, the accumulated charges can be discharged from the pad through the vias of the first conductive path.

Furthermore, the circuit apparatus of the present embodiment includes the substrate of the first conductivity type, the first well of the first conductivity type provided in the substrate, the second well of the second conductivity type provided in the substrate, the pad, and the MIM capacitor having the first electrode, the second electrode, and the dielectric layer provided between the first electrode and the second electrode. The second well and the pad are electrically connected by the first conductive path, one electrode out of the first electrode and the second electrode and the pad are electrically connected by the second conductive path, and the other electrode out of the first electrode and the second electrode and the first well are electrically connected by the third conductive path. The second conductive path includes the first wiring of the metal layer that is the same layer as or a layer above the metal layer of the first electrode, and the second wiring of the metal layer below the metal layer of the first electrode.

According to the present embodiment, one electrode of the capacitor and the pad are electrically connected to each other by the second conductive path in which the path is detoured through the first wiring of the metal layer that is the same layer as or a layer above the first electrode of the capacitor and the second wiring of the metal layer below the first electrode. Since the path is detoured through the first wiring and the second wiring as described above, it is possible to suppress the discharge of the charges in the second conductive path, and it is possible to prevent a situation in which the MIM capacitor is electrostatically destroyed or the like.

The vibration device of the present embodiment includes the circuit apparatus described above, the through electrode provided in the substrate of the circuit apparatus, the vibration element electrically connected to the through electrode, and the lid that accommodates the vibration element together with the substrate.

With this configuration, it is possible to realize a small vibration device, and it is also possible to realize the maximization of the area of the integrated circuit of the circuit apparatus of the vibration device.

While the present embodiment is described in detail as described above, those skilled in the art will easily understand that various modifications can be made without substantially departing from novel matters and effects of the present disclosure. Accordingly, all such modification examples should be construed as falling within the scope of the present disclosure. For example, a term described at least once in the specification or the drawings together with a different term having a broader meaning or the same meaning can be replaced with the different term anywhere in the specification or the drawings. All combinations of the present embodiment and the modification examples also fall within the scope of the present disclosure. In addition, configurations, operations, and the like of the circuit apparatus and the vibration device are not limited to those described in the present embodiment, and various modifications can be made.

What is claimed is:

1. A circuit apparatus comprising:
a substrate of a first conductivity type;
a first well of the first conductivity type provided in the substrate;
a second well of a second conductivity type provided in the substrate;
a pad; and
a MIM capacitor including a first electrode, a second electrode, and a dielectric layer provided between the first electrode and the second electrode, wherein
the second well and the pad are electrically connected by a first conductive path,
one electrode out of the first electrode and the second electrode and the pad are electrically connected by a second conductive path,
another electrode out of the first electrode and the second electrode and the first well are electrically connected by a third conductive path, and
a resistance value of the second conductive path is greater than a resistance value of the first conductive path.

2. The circuit apparatus according to claim 1, wherein
the second conductive path includes first wiring of a metal layer that is a same layer as or a layer above a metal layer of the first electrode.

3. The circuit apparatus according to claim 2, wherein
one end of the first wiring is electrically connected to the one electrode, and another end of the first wiring is electrically connected to the first conductive path.

4. The circuit apparatus according to claim 1, wherein
the second conductive path includes second wiring of a metal layer below a metal layer of the first electrode.

5. The circuit apparatus according to claim 4, wherein
the metal layer of the second wiring is a lowermost metal layer.

6. The circuit apparatus according to claim 1, wherein
the second conductive path includes
first wiring of a metal layer that is a same layer as or a layer above a metal layer of the first electrode, and
second wiring of a metal layer below the metal layer of the first electrode, wherein
the first wiring and the second wiring are electrically connected to each other through a via connecting metal layers.

7. The circuit apparatus according to claim 1, wherein
the substrate and the first well are set to a potential of a first power supply, and
the pad is supplied with a potential different from the potential of the first power supply.

8. The circuit apparatus according to claim 1, wherein
the first conductive path includes a plurality of vias each connecting metal layers.

9. A circuit apparatus comprising:
a substrate of a first conductivity type;
a first well of the first conductivity type provided in the substrate;
a second well of a second conductivity type provided in the substrate;
a pad; and
a MIM capacitor including a first electrode, a second electrode, and a dielectric layer provided between the first electrode and the second electrode, wherein
the second well and the pad are electrically connected by a first conductive path,
one electrode out of the first electrode and the second electrode and the pad are electrically connected by a second conductive path,
another electrode out of the first electrode and the second electrode and the first well are electrically connected by a third conductive path, and
the second conductive path includes
first wiring of a metal layer that is a same layer as or a layer above a metal layer of the first electrode, and
second wiring of a metal layer below the metal layer of the first electrode.

10. A vibration device comprising:
the circuit apparatus according to claim 1;
a through electrode provided in the substrate of the circuit apparatus;
a vibration element electrically connected to the through electrode; and
a lid that accommodates the vibration element together with the substrate.
